(19) United States
(12) Patent Application Publication
(10) Pub. No.: US 2014/0217381 A1
(43) Pub. Date: Aug. 7, 2014

(54) ILLUMINANT WITH AT LEAST ONE ORGANIC LIGHT EMITTING DIODE

(71) Applicant: BJB GmbH & Co. KG, Arnsberg (DE)

(72) Inventors: Karl-Wilhelm Vogt, Ense (DE); Marco Ludwig, Wickede (DE)

(21) Appl. No.: 14/153,013

(22) Filed: Jan. 11, 2014

Related U.S. Application Data
(63) Continuation of application No. PCT/DE2012/000684, filed on Jul. 9, 2012.

(30) Foreign Application Priority Data
Jul. 12, 2011 (DE) 102011107642.9

(51) Int. Cl. H01L 51/52; H01L 27/32

(52) U.S. Cl. CPC H01L 51/5203; H01L 27/32; H01L 2227/32; H01L 2251/5361
USPC 257/40

(57) ABSTRACT

Illustrated and described is an illuminant, including at least one organic light emitting diode which is applied to a carrier material that is vapor deposited with a metal layer which metal layer supplies the at least one organic light emitting diode with voltage and is connectable with connecting conductors, wherein at least one connecting contact is bonded on one side at least to the metal layer and on another side directly fixated in an insulating material housing.

### RELATED APPLICATIONS

This application is a continuation of PCT/DE2012/000684 filed on Jul. 9, 2012 which claims priority from German patent application DE 10 2011 107 642.9 filed on Jul. 12, 2011, both of which are incorporated in their entirety by this reference.

### FIELD OF THE INVENTION

The invention relates to an illuminant including at least one organic light emitting diode (OLED) which is applied to a carrier material which is vapor deposited with a metal layer which is used for supplying the OLED with voltage and connected with conducting leads for this purpose.

### BACKGROUND OF THE INVENTION

Besides using non organic LEDs for replacing conventional illuminants increasingly LEDs are being used that are based on organic semiconductor technology. Illuminants with organic light emitting diodes (OLED) typically include a plate shaped carrier material, in particular glass on which the organic semiconductor components are applied. The voltage and power supply is provided by a metal layer that is vapor deposited on the carrier material. The carrier material is typically provided with a cover, typically another glass plate on its backside. Thus, the organic semiconductor components are supported between the carrier material and the cover. The cover, however, allows access to the metal layer in boundary areas so that the metal layer can be electrically contacted in several ways.

Thus, is it known for example to fixate electrical conductors with a special conductive glue on the metal layer in order to be able to feed electricity. There is also an option to establish a connection with a conductive elastomeric material. Eventually there is a method to attach flexible conductor plates at the metal layer of the carrier material.

These options for electrically connecting illuminants with organic LEDs have their own specific disadvantages. Thus, glue joints are rather sensitive with respect to shear loads. Therefore illuminants that are connected in this manner are typically arranged in housings with separate connecting contacts.

When using electrically conductive elastomeric materials it is required to provide a compression of the elastomeric materials. Therefore also in this case the illuminant has to be pressed against a support. Additionally the transition resistances from elastomeric material to the illuminant are rather high.

Using flexible conductor plates for electrically connecting organic LEDs is only useful for particular applications due to the sensitivity of the electrical conductor plates.

The recited techniques are described for example in manufacturer guidelines for contacting OLEDs.

An option to support illuminants including OLEDs is illustrated for example in DE 20 2006 012 937 and known from WO 2008/074431 A1.

To sum it all up there is an urgent requirement in the art to improve the electrical contacting of illuminants including OLEDs and their support.

### BRIEF SUMMARY OF THE INVENTION

Thus it is an object of the invention to provide an advantageous electrical connection and support of illuminants based on OLEDs.

The object is achieved by an illuminant including at least one organic light emitting diode which is applied to a carrier material that is vapor deposited with a metal layer which metal layer supplies the at least one organic light emitting diode with voltage and is connectable with connecting conductors, wherein at least one connecting contact is bonded on one side at least to the metal layer and on another side directly fixated in an insulating material housing.

It is an essential advantage of the invention that the connecting contact is not only used for supplying the illuminant with power but also for supporting it at another component. Thus, the contact is directly fixated in the insulating material which in turn can be an element of a light, however the insulating material is preferably used as a base for the illuminant. The tasks of electrically contacting and mechanically supporting the illuminant that were considered and solved separately so far are thus united in one component.

For producing the bonded connection between the metal layer of the carrier material and the connecting contact in particular ultra sound soldering is provided. Welding or gluing is also possible.

Typically OLED illuminants are provided with plural connecting contacts per pole in order to provide an even voltage and power supply over the carrier surface provided with OLEDs. Typically plural contacts are provided per pole. When an insulation material housing embeds the illuminant according to an advantageous embodiment and thus forms a socket for the illuminant in a classical sense, identical poles can be electrically connected with one another within the insulation material housing in another preferred embodiment. This has the essential advantage that at least two of the connecting contacts are used for external electrical connection and complex wiring that would be otherwise required is considerably reduced.

It is conceivable and advantageous when the contacts that are connected with the metal layer are indirectly, but in particular directly supported in the insulation material housing so they are accessible from an outside. Thus, electricity can be tapped at the connecting contacts for supplying another illuminant.

The function of the connection contact as a mechanical support element for the illuminant in an insulation material facilitates providing an insulation material housing or a base for the illuminant where in the base terminates with the surface plane of the viewing surface of the illuminant and does not cover the illuminant. Thus uniform flat lights can be produced through arranging plural identical illuminants in series.

### BRIEF DESCRIPTION OF THE DRAWINGS

Additional advantages of the invention can be derived from the subsequent description of an embodiment with reference to drawing Figures, wherein:

FIG. 1. illustrates an illuminant according to the invention in an exploded view;

FIG. 2 illustrates the assembled illuminant according to FIG. 1 in a vertical sectional view; and

FIG. 3 illustrates a partial view of the illuminant according to FIG. 2 looking at a connection contact.

### DETAILED DESCRIPTION OF THE INVENTION

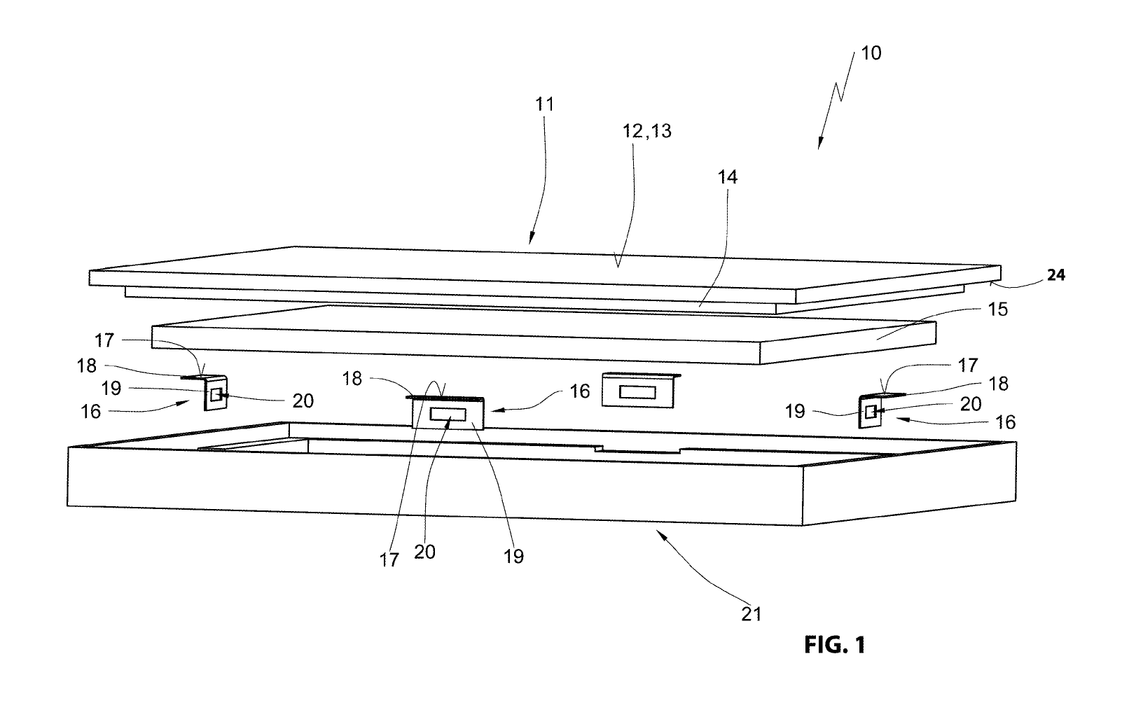

An illuminant according to the invention is overall designated with the reference numeral 10 in the figures. The illuminant 10 includes a carrier plate 11 made from glass wherein a viewing surface 12 that is visible to a viewer and forms the light emitting surface 13 is oriented in upward direction in FIG. 1.

On the bottom side of the carrier plate 11 a metal layer is vapor deposited which is not illustrated in detail and which is freely accessible in an edge portion of the carrier plate 11 and which is used for connecting electrical connections. In a portion that is covered by a cover plate 14 the metal layer forms conductive paths for supplying voltage to organic light emitting diodes (OLED) that are applied to the carrier plate 11. The cover plate 14 is arranged on a side of the carrier plate 11 that is oriented away from the viewing surface so that in particular the OLEDs are arranged between the carrier plate 11 and the cover plate 14.

Below the cover plate 14 a cooling element 15 is illustrated in FIG. 1 wherein the cooling element approximately corresponds to the cover plate 14 with respect to its dimensions and is directly attached at the cover plate 14 in assembled condition of the illuminant 10. The cooling element 15 is used for dissipating heat that is generated during operation of the OLEDs.

Furthermore electrical connecting contacts 16 are illustrated. The electrical connecting contacts have a contact surface 17 that is oriented towards the carrier plate 11, wherein the connecting contacts are arranged with the contact surface at the metal layer that is accessible in an edge portion of the carrier plate 11. The contact surface 17 is formed by a first contact arm 18 of the connecting contact 16. A second contact arm 19 of the connecting contact 16 is arranged in FIG. 1 at a right angle to the first contact arm 18 and provided with a support opening 20. Eventually a frame shaped insulating material housing 21 is illustrated in FIG. 1, wherein the insulating material housing receives the components described supra.

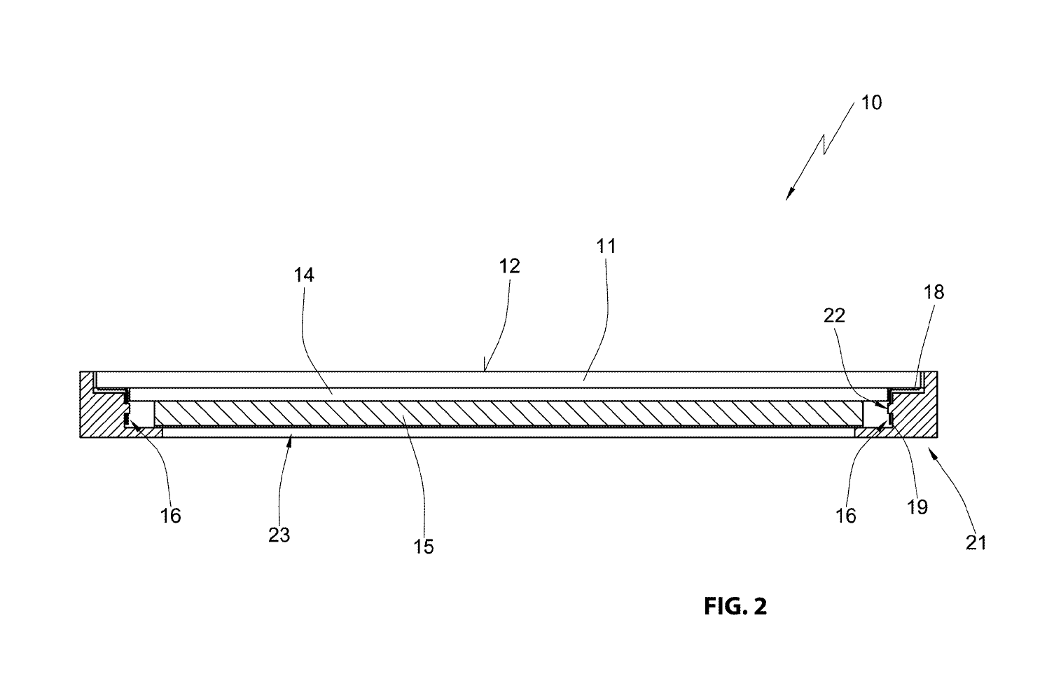

FIG. 2 describes a vertical sectional view through the illuminant 10 that is illustrated in FIG. 1. The illuminant 10 in FIG. 2 is assembled. As apparent from FIG. 2 the insulating material housing 21 terminates with the plane of the viewing surface 1. No elements of the insulating material 21 cover the viewing surface 1.

The connecting contacts 16 are bonded through the contact surface 17 of the first contact arm 18 to the metal layer vapor deposited on the bottom side of the carrier plate 11. The support opening 20 of the second contact arm 19 is penetrated by a support pin 22 which is formed by the insulation material housing 21. The cooling element 15 is arranged at the cover plate 14. In order to optimize the heat transition from the cover plate 14 to the cooling element 15 a heat conducting paste or foil can be provided in the portion of the adjacent surfaces. The base portion of the insulation material housing 21 which base portion is adjacent to the cooling element 15 is provided with a recess 23. Through this recess it is possible to contact another light side cooling element with the cooling element 15 of the illuminant 10 in order to further improve heat dissipation.

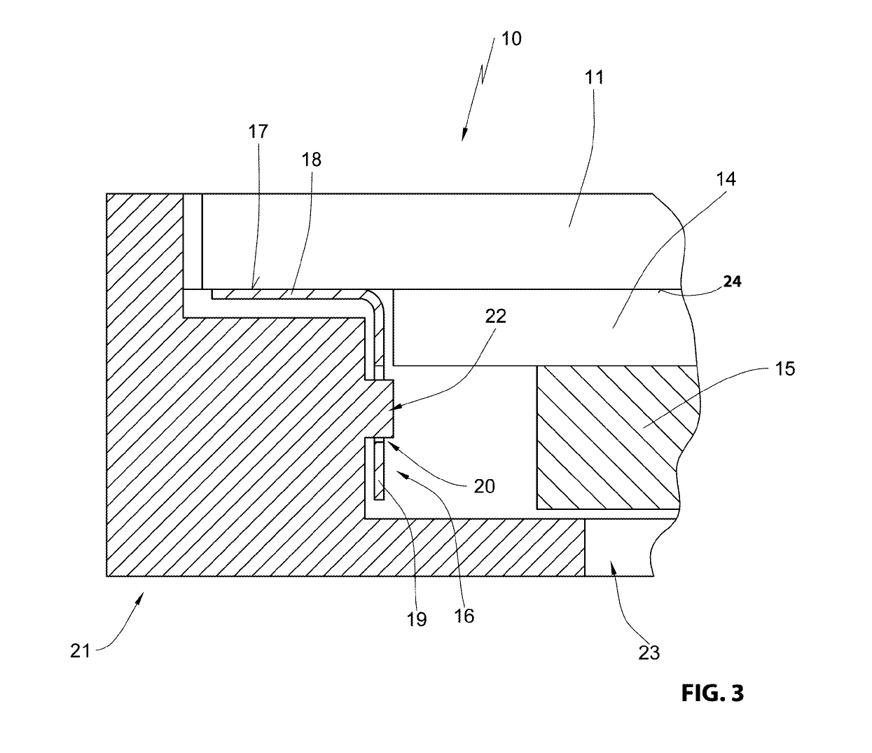

FIG. 3 illustrates the left section of the illuminant 10 with respect to FIG. 2. This illustration shows the anchoring of the connection contact 16 in the insulation material housing 21 particularly clearly. The support pin 22 reaching through the support opening 20 of the second contact arm 19 provides form locking between the insulation material housing 21 and the connecting contact 16. Between the first contact arm 18 and the metal layer 24 of the carrier plate 11 material bonding is established. This is preferably performed through ultrasound soldering. Other material bonding connections like welding or gluing, however are conceivable.

In order to support the light element including the carrier plate 11, the cover plate 14, and the OLEDs supported there between, wherein the light element is supplemented with a cooling element 15 when required, in the insulating material housing to form the illuminant 10 according to the invention, the material bonding of the first contact arm 18 in combination with the form locking of the second contact arm 19 is completely sufficient. In so far the connecting contact 16 is also used for mechanical support besides being used for electrical contacting. This is one of the essential advantages of the illuminant according to the invention.

Typically, as described supra and illustrated herein, several contacts are electrically contacted with the metal layer in order to keep the distribution of the voltage and current over the surface of the carrier plate 11 provided with OLEDs uniform. This requires in the prior art that connecting contacts with identical polarity respectively have to be individually provided with external connecting conductors. According to the invention, however, it is possible to provide the electrical connection of identical poles with one another within the insulation material housing 21 so that the external wiring only has to be provided through two contacts. For this purpose the contact 16 can be provided with suitable connecting elements. Contacts configured as knife-wedge contacts or compression contacts or screw-less cable contacts are conceivable.

It is furthermore possible to tap electricity from the connecting contacts 16 and to use it for supplying voltage to another illuminant in a loop connection. This is particularly advantageous in combination with the electrical connection provided within the insulation material housing through separate connection elements since the voltage supply does not have to be provided through the metal layer then.

In the configuration illustrated in the Figures the light element is provided with a base through the insulating material housing 21 wherein the base significantly simplifies handling and mounting of illuminants 10 provided with OLEDs and gives options for providing effective base-socket systems.

However, it is also conceivable that individual insulating material housings are only provided in the portion of some contacts. It is also feasible that the light element is provided with connecting contacts but does not include any insulating material housing as directly associated component. Then one or plural insulating material housings have to be provided, for example as light elements into which the connecting contacts 16 are insertable. The connection between contact and insulating material housing can then be provided for example through friction locking, wherein electrical contacting with connecting conductors can be provided through knife-clamping techniques simultaneously with inserting the contacts into the insulation material housing. Other forms of fixating connecting contacts 16 that support the illuminant 10 in the insulating material housing are feasible.

### REFERENCE NUMERALS AND DESIGNATIONS

10 Illuminant

11 Carrier Plate

12 Viewing Surface

13 Light Emitting Surface

14 Cover Plate

15 Cooling Element

16 Electrical Connecting Contacts

17 Contact Surface

18 First Contact Arm

19 Second Contact Arm

20 Support Opening

21 Insulating Material Housing

22 Support Pin

23 Recess

24 Metal Layer

What is claimed is:

1. An illuminant, comprising:
at least one organic light emitting diode which is applied to a carrier material that is vapor deposited with a metal layer which metal layer supplies the at least one organic light emitting diode with voltage and is connectable with connecting conductors,
wherein at least one connecting contact is bonded on one side at least to the metal layer and on another side directly fixated in an insulating material housing.

2. The illuminant according to claim 1, wherein the at least one connecting contact that is directly fixated in the insulating material housing is directly connectable with the connecting conductors.

3. The illuminant according to claim 1,
wherein the metal layer forms plural poles and plural connecting contacts are bonded to the metal layer,
wherein connecting contacts of identical poles are electrically connected with one another within the insulating material housing.

4. The illuminant according to claim 1, wherein at least one connecting contact that is fixated in the insulating material housing is accessible to provide an additional illuminant with electricity through an electrical connection.

5. The illuminant according to claim 1, wherein the insulating material housing includes a cooling element which dissipates heat generated by operating the at least one organic light emitting diode.

6. The illuminant according to claim 1, wherein the material bonding between the connecting contact and the metal layer is provided through ultrasound soldering, welding, or gluing.

7. The illuminant according to claim 1,
wherein the illuminant is embedded in the insulating material housing, and
wherein the insulating material housing forms a base which is supportable in an essentially form- and connection complementary socket portion.

8. The illuminant according to claim 1, wherein the illuminant is exclusively supported at the insulation material housing on one side through a connection between the at least one connecting contact and the carrier material and on the other side through the fixation of the at least one connecting contact in the insulating material housing.

9. The illuminant according to claim 7, wherein the insulation material housing does not cover a viewing surface of the illuminant and in particular terminates with a surface plane of the viewing surface.

10. The illuminant according to claim 8, wherein the insulation material housing does not cover a viewing surface of the illuminant and in particular terminates with a surface plane of the viewing surface.
